(19) United States
(12) Patent Application Publication
(10) Pub. No.: US 2025/0212443 A1
(43) Pub. Date: Jun. 26, 2025

(54) METHOD OF MANUFACTURING FIN IN TRANSISTOR AND METHOD OF MANUFACTURING FIN FIELD EFFECT TRANSISTOR

(71) Applicant: INSTITUTE OF MICROELECTRONICS, CHINESE ACADEMY OF SCIENCES, Beijing (CN)

(72) Inventors: Junfeng LI, Beijing (CN); Peng WANG, Beijing (CN); Guanqiao SANG, Beijing (CN); Lei CAO, Beijing (CN); Renjie JIANG, Beijing (CN); Qingkun LI, Beijing (CN); Qingzhu ZHANG, Beijing (CN); Huaxiang YIN, Beijing (CN); Jun LUO, Beijing (CN); Yihong LU, Beijing (CN); Wenjuan XIONG, Beijing (CN)

(21) Appl. No.: 18/905,290

(22) Filed: Oct. 3, 2024

(30) Foreign Application Priority Data
Dec. 22, 2023 (CN) 202311785167.9

(51) Int. Cl. H01L 29/66; H01L 21/311; H01L 21/8234; H01L 27/088; H01L 29/08; H01L 29/78

(52) U.S. Cl. CPC H10D 30/024; H01L 21/31105; H10D 30/62; H10D 62/151; H10D 64/017; H10D 84/013; H10D 84/0158; H10D 84/038; H10D 84/834

(57) ABSTRACT

The present disclosure relates to a method of manufacturing a fin in a transistor and a method of manufacturing a fin field effect transistor. The method of manufacturing the fin in the transistor includes: epitaxially growing a semiconductor layer on a substrate; etching the semiconductor layer into a fin-shaped portion by using a spacer transfer technique; oxidizing a sidewall of the fin-shaped portion with ozone, so as to form an oxide film on the sidewall; and etching the oxide film by using an atomic layer etching method, so as to remove the oxide film.

### CROSS REFERENCE TO RELATED APPLICATION

This application claims priority to Chinese Patent Application No. 202311785167.9, filed on Dec. 22, 2023, the entire content of which is incorporated herein in its entirety by reference.

### TECHNICAL FIELD

The present disclosure relates to the field of transistors, and in particular to a method of manufacturing a fin in a transistor and a method of manufacturing a fin field effect transistor.

### BACKGROUND

From the node of 14 nm, fin field effect transistors (FinFET) become a mainstream technology for advanced integrated circuit processes internationally. In the advanced FinFET technology, fins are manufactured by using a self-aligned multiple-exposure process. However, during a manufacturing process of a fin, organic molecular chains of a photoresist fail to be perfectly broken in accordance with the designed pattern, resulting in a high line edge roughness (LER) and a high line width roughness (LWR) of the fin. There may be more defects and impurities on a rough fin surface, and these defects and impurities may form local energy levels near an interface. These local energy levels will capture and ionize electrons, resulting in a high interface state density Dᵢₜ.

### SUMMARY

According to a first aspect of the present disclosure, a method of manufacturing a fin in a transistor is provided, including:
epitaxially growing a semiconductor layer on a substrate;
etching the semiconductor layer into a fin-shaped portion by using a spacer transfer technique;
oxidizing a sidewall of the fin-shaped portion with ozone, so as to form an oxide film on the sidewall; and
etching the oxide film by using an atomic layer etching method, so as to remove the oxide film.

Furthermore, a thickness of the oxide film is less than 0.7 nm.

Furthermore, a reaction gas used in the atomic layer etching method includes HF.

Furthermore, the oxidizing a sidewall of the fin-shaped portion with ozone and the etching the oxide film by using an atomic layer etching method are repeated for a plurality of times, and each of repetitions includes: performing the oxidizing a sidewall of the fin-shaped portion with ozone and the etching the oxide film by using an atomic layer etching method in sequence.

Furthermore, a number of the repetitions is in a range of 8 to 12.

According to a second aspect of the present disclosure, a method of manufacturing a fin field effect transistor is provided, including:
providing a substrate;
epitaxially growing a semiconductor layer on the substrate;
etching the semiconductor layer into a fin-shaped portion by using a spacer transfer technique;
oxidizing a sidewall of the fin-shaped portion with ozone, so as to form an oxide film on the sidewall;
etching the oxide film by using an atomic layer etching method, so as to remove the oxide film and form a fin;
forming a shallow trench isolation;
forming a dummy gate;
forming a spacer;
forming a source/drain;
removing the dummy gate;
forming a gate; and
leading out an electrode.

Furthermore, a thickness of the oxide film is less than 0.7 nm.

Furthermore, a reaction gas used in the atomic layer etching method includes HF.

Furthermore, before the shallow trench isolation is formed, the oxidizing a sidewall of the fin-shaped portion with ozone and the etching the oxide film by using an atomic layer etching method are repeated for a plurality of times, and each of repetitions includes: performing the oxidizing a sidewall of the fin-shaped portion with ozone and the etching the oxide film by using an atomic layer etching method in sequence.

Furthermore, a number of the repetitions is in a range of 8 to 12.

### BRIEF DESCRIPTION OF THE DRAWINGS

By reading the following detailed description of the preferred embodiments, those of ordinary skilled in the art will understand various additional advantages and benefits of the present disclosure. The accompanying drawings are only for illustrating the preferred embodiments and are not to be construed as limiting the present disclosure.

FIG. 1 is a morphology of a fin manufactured using a conventional FinFET manufacturing process;

FIG. 2 is a schematic diagram of a marking of LER of the fin in FIG. 1;

FIG. 3 is a schematic diagram of a marking of LWR of the fin in FIG. 1;

FIG. 4 is a SEM image of a fin to be treated according to an embodiment of the present disclosure;

FIG. 5 is a SEM image of the fin in FIG. 4 after being repeatedly treated for 8 times;

FIG. 6 is a SEM image of the fin in FIG. 4 after being repeatedly treated for 12 times; and

FIG. 7 is a comparison diagram of changes in LER and LWR of the fin in FIG. 4 before and after being treated.

### DETAILED DESCRIPTION OF EMBODIMENTS

Embodiments of the present disclosure will be described below with reference to the accompanying drawings. However, it will be understood that these descriptions are exemplary only and are not intended to limit the scope of the present disclosure. In addition, in the following description, descriptions of well-known structures and techniques are omitted to avoid unnecessarily confusing the concept of the present disclosure.

The drawings show various structural schematic diagrams according to the embodiments of the present disclosure. The drawings are not drawn to scale, and for the sake of clarity, some details may be exaggerated and some details may be omitted. The shapes, relative sizes and relative positions of the various regions and layers shown in the drawings are merely exemplary and may deviate in practice due to manufacturing tolerances or technical limitations. In addition, those skilled in the art may also design regions/layers with different shapes, sizes and relative positions according to actual needs.

In the present disclosure, when a layer/element is referred to as being “on” a further layer/element, the layer/element may be directly on the further layer/element, or an intervening layer/element may be provided therebetween. In addition, if a layer/element is “on” a further layer/element in an orientation, the layer/element may be “below” the further layer/element when the orientation is reversed.

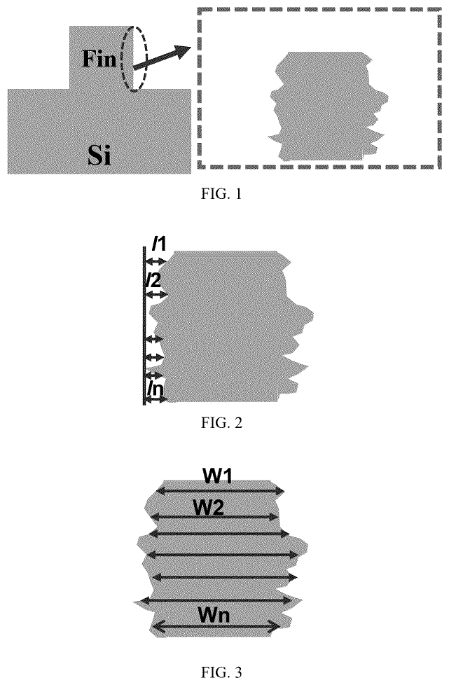

In a conventional manufacturing process of a fin of FinFET, organic molecular chains of a photoresist fail to be perfectly broken in accordance with the designed pattern, resulting in a high line edge roughness (LER) and a high line width roughness (LWR) of the fin, as shown in FIG. 1. There may be more defects and impurities on a rough fin surface, and these defects and impurities may form local energy levels near an interface. These local energy levels will capture and ionize electrons, resulting in a high interface state density Dᵢₜ. LER is a parameter for evaluating linear profile fluctuations, which characterizes vertical or horizontal fluctuations of an edge of a line, as shown in FIG. 2. LER may be quantified with statistics for vertical or horizontal peaks and valleys on the line. The calculation equation of LER is as follows. Too high LER in a transistor may lead to unstable device performance.

$$〈 LER 〉 = \sqrt{1 / N {\sum }_{i = 1}^{N} {l}_{i} ( t ) - {\overline{l ( t )}}^{2}}$$

LWR is a parameter for characterizing a line width variation, namely measured fluctuations of the line width, as shown in FIG. 3. LWR is generally quantified with statistics for the degree of dispersion between different widths of the line. Too high LWR may cause poor resistance performance and degrade the device speed and reliability. The calculation equation of LWR is as follows.

$$〈 LWR 〉 = \sqrt{1 / N {\sum }_{i = 1}^{N} {w}_{i} ( t ) - {\overline{w ( t )}}^{2}}$$

The impact of LER and LWR on the device performance is mainly reflected in the carrier mobility. The carrier mobility is an important parameter to measure the conductivity of a semiconductor, which directly affects the device performance of FinFET. The mobility is microscopically defined as μ=eτ/m*, where τ is a time interval between electron collisions and m* is an effective mass of the carrier. The main factors affecting the carrier mobility at the interface are acoustic scattering and surface roughness scattering. The electron mobility may be expressed as: μ=μ_{P}*μ_{SR}/μₚ+μ_{SR}, where μ_{P} is a mobility limited by the acoustic scattering, and μ_{SR} is a mobility limited by the roughness scattering. A fin surface with a high interface state density often has poor atomic periodicity, thus μ_{P} is small. In addition, high surface roughness will increase the scattering of carriers on the material surface, thereby reducing μ_{SR} and causing degradation of the device performance. Therefore, reducing the fin roughness and the interface state density may improve the device performance.

To address the problem of high LER and high LWR of the fin, thermal oxidation, hydrogen heat treatment and thermal annealing may be used to reduce the roughness. However, these methods all have problems such as excessive process temperature and obvious overshoot. Excessive temperature may increase the risk of damage to the device. Overshoot refers to a phenomenon that the roughness and the interface state density first decrease and then increase as the number of treatments increases or the treatment time increases, resulting in the problem not being solved or even being aggravated.

The main objectives of the present disclosure are to provide a method of manufacturing a fin in a transistor and a method of manufacturing a fin field effect transistor, so as to reduce the fin roughness and the interface state density, thereby improving the device performance.

The present disclosure proposes a method of reducing the linear roughness and the interface state density of a fin in a transistor. The method includes: after a semiconductor layer is epitaxially grown on a substrate, etching the semiconductor layer into a fin-shaped portion by using a spacer transfer technique, and then performing an “oxidizing plus etching” treatment or repeatedly performing the following steps for a plurality of times.

First, a sidewall of the fin-shaped portion is oxidized with ozone, so as to form an oxide film on the sidewall. Since ozone has a strong oxidizing property, ozone is capable of quickly oxidizing a semiconductor at room temperature to form an oxide film with a thickness of several angstroms. In this way, damage to the device caused by high temperature may be avoided, and excessive oxidation may be prevented.

Next, atomic layer etching (ALE) is used to remove the oxide film formed in the previous step. HF (dHF) cleaning may be used to remove a SiO₂ film. ALE has advantages such as precise etching control, good uniformity and small load effect, which is capable of avoiding overshoot.

Depending on the LER and LWR conditions of the fin, the above steps may be repeatedly performed for a plurality of times until the fin surface is smooth enough. For example, in some embodiments, the number of the repetitions is in a range of 8 to 12.

The repetitions of oxidation for a plurality of times may achieve more accurate control of a thinning size, so as to avoid overshoot.

In some embodiments, after the oxidation is repeatedly performed for a plurality of times, the total thickness of the film may be controlled to be less than 0.7 nm.

Normally, the strong oxidizing property of ozone is capable of quickly oxidizing a surface of the sidewall of the fin, forming an extremely thin oxide film. Further controlling the thickness of the oxide film to be less than 0.7 nm may avoid significant impact on the structural stability of the fin.

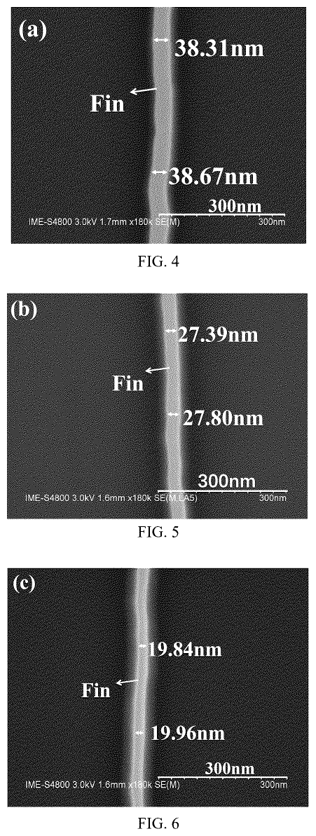

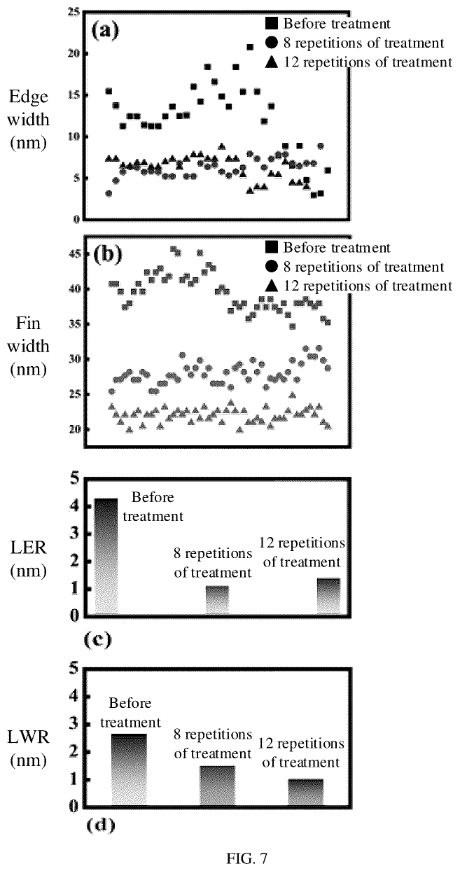

Taking the fin with the morphology shown in FIG. 4 as an example, after the “oxidizing plus etching” is repeatedly performed for 8 times, the morphology shown in FIG. 5 is obtained, and after the “oxidizing plus etching” is repeatedly performed for 12 times, the morphology shown in FIG. 6 is obtained. In addition, 30 positions are randomly selected for measurement of the line edge width of the fin, and 50 positions are randomly selected for measurement of the line width of the fin. Then, the LER and the LWR of each set of data are calculated. In FIG. 7, (a) and (b) respectively show a scatter plot graph of the line edge width and a scatter plot graph of the line width before and after the “oxidizing plus etching”; and (c) and (d) respectively show LER and LWR data before and after peeling. It is found from comparison that after 12 repeated treatments, LER and LWR respectively decrease by 67.4% (from 4.30 nm to 1.40 nm) and 61.3% (from 2.66 nm to 1.03 nm). Therefore, the method in the present disclosure is possible to accurately fine-tune the morphology of the fin, and the roughness may be greatly reduced without sharply reducing the fin width.

Therefore, using the method combining ozone oxidation with atomic layer etching in the present disclosure to process the fin may eliminate the unevenness and the interface state on the fin surface, reduce the fin roughness, and improve the surface smoothness, thereby reducing the interface state density. In addition, since both the ozone oxidation and the atomic layer etching are performed at room temperature, damage to the device structure caused by high temperature may be avoided.

In addition, the above-mentioned method of manufacturing the fin is applicable for manufacturing transistors with fin structures, such as FinFET and GAAFET, which is not limited to the FinFET listed below.

Other steps in the manufacturing of the transistor may be performed subsequently. Taking the manufacturing of FinFET as an example, the subsequent steps include: forming a shallow trench isolation; forming a dummy gate; forming a spacer; forming a source/drain; removing the dummy gate; forming a gate; and leading out an electrode. The leading out an electrode mainly refers to forming a contact hole, filling the contact hole and performing a metallization treatment. The above steps may all refer to the manufacturing process of conventional FinFET.

Therefore, in the present disclosure, the fin surface is more smooth through the ozone oxidation combined with the atomic layer etching, so that a transistor formed on this basis has a low interface state density and a high carrier mobility.

In addition, according to the present disclosure, there is no particular limitation on the semiconductor material for forming the substrate and the fin, which may be silicon, silicon germanium, etc.

If the above method is used to manufacture a fin in GAAFET, the fin refers to a stack of two semiconductor materials used to form a nanosheet, which will not be described in details here.

In summary, compared with the related art, the present disclosure achieves the following technical effects: the fin is treated by the ozone oxidation combined with the atomic layer etching, and after the ozone oxidation and the atomic layer etching are repeatedly performed for a plurality of times, the unevenness and the interface state on the fin surface may be eliminated, the fin roughness may be reduced, and the surface smoothness may be improved, thereby reducing the interface state density. In addition, since both the ozone oxidation and the atomic layer etching are performed at room temperature, damage to the device structure caused by high temperature may be avoided.

The embodiments of the present disclosure are described above. However, these embodiments are for illustrative purposes only and are not intended to limit the scope of the present disclosure. The scope of the present disclosure is defined in accordance with the appended claims and their equivalents. Without departing from the scope of the present disclosure, those skilled in the art may make various substitutions and modifications, all of which should fall within the scope of the present disclosure.

What is claimed is:

1. A method of manufacturing a fin in a transistor, comprising:
epitaxially growing a semiconductor layer on a substrate;
etching the semiconductor layer into a fin-shaped portion by using a spacer transfer technique;
oxidizing a sidewall of the fin-shaped portion with ozone, so as to form an oxide film on the sidewall; and
etching the oxide film by using an atomic layer etching method, so as to remove the oxide film.

2. The method according to claim 1, wherein a thickness of the oxide film is less than 0.7 nm.

3. The method according to claim 1, wherein a reaction gas used in the atomic layer etching method comprises HF.

4. The method according to claim 1, wherein the oxidizing a sidewall of the fin-shaped portion with ozone and the etching the oxide film by using an atomic layer etching method are repeated for a plurality of times, and each of repetitions comprises: performing the oxidizing a sidewall of the fin-shaped portion with ozone and the etching the oxide film by using an atomic layer etching method in sequence.

5. The method according to claim 2, wherein the oxidizing a sidewall of the fin-shaped portion with ozone and the etching the oxide film by using an atomic layer etching method are repeated for a plurality of times, and each of repetitions comprises: performing the oxidizing a sidewall of the fin-shaped portion with ozone and the etching the oxide film by using an atomic layer etching method in sequence.

6. The method according to claim 3, wherein the oxidizing a sidewall of the fin-shaped portion with ozone and the etching the oxide film by using an atomic layer etching method are repeated for a plurality of times, and each of repetitions comprises: performing the oxidizing a sidewall of the fin-shaped portion with ozone and the etching the oxide film by using an atomic layer etching method in sequence.

7. The method according to claim 4, wherein a number of the repetitions is in a range of 8 to 12.

8. A method of manufacturing a fin field effect transistor, comprising:
providing a substrate;
epitaxially growing a semiconductor layer on the substrate;
etching the semiconductor layer into a fin-shaped portion by using a spacer transfer technique;
oxidizing a sidewall of the fin-shaped portion with ozone, so as to form an oxide film on the sidewall;
etching the oxide film by using an atomic layer etching method, so as to remove the oxide film and form a fin;
forming a shallow trench isolation;
forming a dummy gate;
forming a spacer;
forming a source/drain;
removing the dummy gate;
forming a gate; and
leading out an electrode.

9. The method according to claim 8, wherein a thickness of the oxide film is less than 0.7 nm.

10. The method according to claim 8, wherein a reaction gas used in the atomic layer etching method comprises HF.

11. The method according to claim 8, wherein before the shallow trench isolation is formed, the oxidizing a sidewall of the fin-shaped portion with ozone and the etching the oxide film by using an atomic layer etching method are repeated for a plurality of times, and each of repetitions comprises: performing the oxidizing a sidewall of the fin-shaped portion with ozone and the etching the oxide film by using an atomic layer etching method in sequence.

12. The method according to claim 9, wherein before the shallow trench isolation is formed, the oxidizing a sidewall of the fin-shaped portion with ozone and the etching the oxide film by using an atomic layer etching method are repeated for a plurality of times, and each of repetitions comprises: performing the oxidizing a sidewall of the fin-shaped portion with ozone and the etching the oxide film by using an atomic layer etching method in sequence.

13. The method according to claim 10, wherein before the shallow trench isolation is formed, the oxidizing a sidewall of the fin-shaped portion with ozone and the etching the oxide film by using an atomic layer etching method are repeated for a plurality of times, and each of repetitions comprises: performing the oxidizing a sidewall of the fin-shaped portion with ozone and the etching the oxide film by using an atomic layer etching method in sequence.

14. The method according to claim 11, wherein a number of the repetitions is in a range of 8 to 12.
